(19) United States
(12) Patent Application Publication
(10) Pub. No.: US 2015/0366098 A1
(43) Pub. Date: Dec. 17, 2015

(54) Wrist Band Attachment for a Wearable Device

(71) Applicant: Google Inc., Mountain View, CA (US)

(72) Inventors: John Lapetina, Los Altos Hills, CA (US); Christopher Jones, San Francisco, CA (US)

(21) Appl. No.: 14/303,507

(22) Filed: Jun. 12, 2014

(51) Int. Cl. H05K 7/02

(52) U.S. Cl. CPC H05K 7/02

(57) ABSTRACT

A wearable device includes an electronics module having a first peripheral mating surface extending around a periphery of the electronics module. The first peripheral mating surface includes a first level portion and a second level portion. The second level portion is substantially concentric with the first level portion. The second level portion is configured to meet the first level portion at the periphery of the electronics module to form a step. The wearable device also includes a strap configured for removable placement about an external body surface. The wearable device further includes a holder coupled to the strap. The holder defines a frame configured to receive the electronics module. The frame includes a second peripheral mating surface opposing the first peripheral mating surface of the electronics module. The second peripheral mating surface includes a respective step configured to mate with the step of the first peripheral mating surface.

### BACKGROUND

Unless otherwise indicated herein, the materials described in this section are not prior art to the claims in this application and are not admitted to be prior art by inclusion in this section.

Wearable devices may be used to obtain information about the wearer's physical activity and/or health state. For example, a wearable device may include one or more motion sensors, such as an accelerometer or gyroscope, in order to detect movements of the wearer and determine the wearer's level of physical activity (e.g., in terms of steps taken or calories burned). Alternatively or additionally, a wearable device may include one or more biological sensors that measure biological parameters of the wearer. The measured biological parameters could include pulse rate, blood oxygenation (oximetry), blood pressure, skin temperature, galvanic skin response (GSR), or other parameters that may relate to the wearer's level of physical exertion.

### SUMMARY

The present disclosure describes embodiments that relate to wrist band attachment for a wearable device. In one aspect, the present application describes a wearable device. The wearable device includes an electronics module having a first peripheral mating surface extending around a periphery of the electronics module. The first peripheral mating surface includes a first level portion and a second level portion. The second level portion is substantially concentric with and extends from the first level portion, and the second level portion is configured to meet the first level portion at the periphery of the electronics module to form a step. The wearable device also includes a strap configured for removable placement about an external body surface. The wearable device further includes a holder coupled to the strap. The holder defines a frame configured to receive the electronics module. The frame includes a second peripheral mating surface opposing the first peripheral mating surface of the electronics module. The second peripheral mating surface includes a respective step configured to mate with the step of the first peripheral mating surface.

In another aspect, the present disclosure describes a method. The method includes securing an electronics module within a holder coupled to a strap to form a wearable device. The electronics module includes a first peripheral mating surface extending around a periphery of the electronics module. The first peripheral mating surface includes a first level portion and a second level portion. The second level portion is substantially concentric with and extends from the first level portion. The second level portion is configured to meet the first level portion at the periphery of the electronics module to form a step. The strap is configured for removable placement about an external body surface. The holder defines a frame configured to receive the electronics module. The frame includes a second peripheral mating surface opposing the first peripheral mating surface of the electronics module. The second peripheral mating surface includes a respective step configured to mate with the step of the first peripheral mating surface as the electronics module is secured within the holder. The frame defines an opening over the external body surface. The electronics module includes a biological sensor configured to obtain one or more measurements via the external body surface through the opening defined by the frame. The method also includes mounting the wearable device to the external body surface such that the opening is over the external body surface. The method further includes causing the biological sensor coupled to the electronics module to obtain the one or more measurements via the external body surface through the opening defined by the frame. The method also includes receiving, from the wearable device, a user-discernible indication of the one or more measurements.

The foregoing summary is illustrative only and is not intended to be in any way limiting. In addition to the illustrative aspects, embodiments, and features described above, further aspects, embodiments, and features will become apparent by reference to the figures and the following detailed description.

### BRIEF DESCRIPTION OF THE FIGURES

FIG. 1 is a perspective view of an example wearable device, in accordance with an example embodiment.

FIG. 2A is a perspective top view of an example wrist-mountable device, when mounted on a wearer's wrist, in accordance with an example embodiment.

FIG. 2B is a perspective bottom view of the example wrist-mountable device shown in

FIG. 2A, when mounted on a wearer's wrist, in accordance with an example embodiment.

FIG. 3A is a perspective bottom view of an example wrist-mountable device, when mounted on a wearer's wrist, in accordance with an example embodiment.

FIG. 3B is a perspective top view of the example wrist-mountable device shown in

FIG. 3A, when mounted on a wearer's wrist, in accordance with an example embodiment.

FIG. 3C is a perspective view of the example wrist-mountable device shown in FIGS. 3A and 3B, in accordance with an example embodiment.

FIG. 4A is a perspective view of an example wrist-mountable device, in accordance with an example embodiment.

FIG. 4B is a perspective bottom view of the example wrist-mountable device shown in

FIG. 4A, in accordance with an example embodiment.

FIG. 5A illustrates a wearable device including an electronics module and a wrist band, in accordance with an example embodiment.

FIG. 5B illustrates a plurality of magnets positioned relative to a frame of the wrist band, in accordance with an example embodiment.

FIG. 5C illustrates the electronics module having a plurality of magnets, in accordance with an example embodiment.

FIG. 5D illustrates a snap configuration for attaching the electronics module to the wrist band, in accordance with an example embodiment.

FIG. 6 is a functional block diagram of an example wearable device, in accordance with an example embodiment.

FIG. 7 is a flow chart of a method of using a wearable device, in accordance with an example embodiment.

### DETAILED DESCRIPTION

The following detailed description describes various features and functions of the disclosed systems and methods with reference to the accompanying figures. In the figures, similar symbols identify similar components, unless context dictates otherwise. The illustrative system and method embodiments described herein are not meant to be limiting. It may be readily understood that certain aspects of the disclosed systems and methods can be arranged and combined in a wide variety of different configurations, all of which are contemplated herein.

### I. OVERVIEW

A body-mountable or wearable device may be configured to measure one or more physiological parameters of a wearer. An example wearable device may include a core electronics module. The core electronics module may include, for example, a peripheral mating surface extending around a periphery of the electronics module.

The wearable device may also include a strap configured for removable placement about an external body surface (e.g., a wrist location). A holder may be coupled to the strap, and the holder defines a frame configured to receive the electronics module. To receive the electronics module within the frame, the frame may be configured to have a respective peripheral mating surface opposing the peripheral mating surface of the electronics module.

In one example, to secure the electronics module within the frame, a plurality of magnets may be positioned relative to the frame. The magnets are configured to exert a magnetic force on the electronics module to secure the electronics module within the frame. The electronics module may include a respective plurality of magnets that corresponds to the plurality of magnets positioned relative to the frame. In this case, the magnetic force results from interaction between the plurality of magnets positioned relative to the frame and the corresponding plurality of magnets in the electronics module.

In another example, alternative to or in addition to using magnets to secure the electronics module within the frame, a snap configuration may be used. For instance, the frame may be configured to have one or more protruding male portions that protrude from the peripheral mating surface of the frame. The electronics module may be configured to have one or more recessed female portions in the peripheral mating surface of the electronics module corresponding to the one or more protruding male portions of the frame. In this case, as the electronics module is received in the frame, the one or more protruding male portions and the recessed female portions engage in a snap configuration so as to secure the electronics module within the frame.

### II. EXAMPLE WEARABLE DEVICES

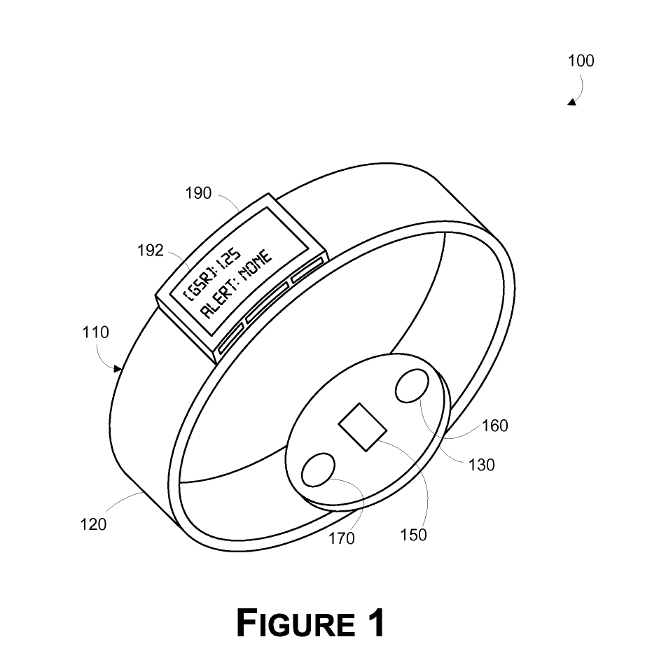

With reference to FIG. 1, a wearable device 100 can be configured to measure one or more physiological parameters via an external body surface proximate to the wearable device 100. The one or more physiological parameters may include, for example, pulse rate, blood oxygenation (oximetry), blood pressure, skin temperature, galvanic skin response (GSR), or other parameters that may relate to the wearer's level of physical exertion. Alternatively or additionally, the one or more physiological parameters may include the presence or absence of one or more clinically-relevant analytes, such as glucose, cholesterol, proteins, enzymes, cells, etc., that may relate to a health state of the wearer. The term “wearable device,” as used in this disclosure, refers to any device that is capable of being worn at, on or in proximity to an external body surface, such as a wrist, ankle, waist, chest, or other body part.

A mount 110, such as a belt, wristband, ankle band, etc. can be provided to mount the device at, on or in proximity to the external body surface. In some embodiments, the mount could additionally or alternatively include an adhesive. For example, a mount could include and adhesive and could be configured such that it could be used to mount a wearable device to an external body surface of a wearer without wrapping around a part of the wearer (e.g., a limb). The mount 110 may prevent the wearable device 100 from moving relative to the body so as to provide sufficient proximity between the wearable device 100 and the skin to enable measurement of the one or more physiological parameters. In one example, shown in FIG. 1, the mount 110, may take the form of a strap or band 120 that can be worn around a part of the body.

A housing 130 is disposed on the mount 110 such that the housing 130 can be positioned on an external surface of the body. In an example, a first electrical contact 160 and a second 170 electrical can protrude from the housing 130 to contact skin at the external surface of the body such that the GSR of the skin at the external surface of the body could be measured between the first and second electrical contacts 160, 170. The first and second electrical contacts 160, 170 could be configured to interface with a charger or other device such that a rechargeable battery that powers the wearable device 100 could be charged through the first and second electrical contacts 160, 170.

The first and second electrical contacts 160, 170 could be composed of an electrically conductive material, such as a metal or a combination of metals, or a nonmetal conductor. The first electrical contact 160 and second electrical contact 170 could be composed of the same material or different materials. The first and second electrical contacts 160, 170 could each be composed of a single material or could be composed of multiple materials. For example, the electrical contacts 160, 170 could have a bulk composed of one material and a surface plating of another material. For example, the electrical contacts 160, 170, could have a bulk composed of copper and a surface composed of gold or of gold alloyed with nickel and/or cobalt. The surface layer could be deposited by a number of methods familiar to one skilled in the art; for example, electroplating. Other compositions are possible, as well.

The first and second electrical contacts 160, 170 could be spring loaded. That is, the electrical contacts 160, 170 could be configured to include one or more springs or other elements that could be reversibly compressed. The electrical contacts 160, 170 could be spring loaded in a direction perpendicular to an external surface of the body to which the housing 130 could be mounted. That is, the electrical contacts 160, 170 could be spring loaded in order to improve and/or make more consistent an electrical connection between the electrical contacts 160, 170 and skin of the external body surface to which the housing 130 was mounted by the mount 110. Alternatively, first and second electrical contacts 160, 170 could be fixed relative to housing 130.

The geometry of the aspects of the electrical contacts 160, 170 that protrude from the housing 130 could be configured to improve and/or make more consistent an electrical connection between the electrical contacts 160, 170 and skin of the external body surface to which the housing 130 was mounted by the mount 110. For example, the protruding aspects of the electrical contacts 160, 170 could be hemispherical, conical, parabolic, cylindrical, or shaped in some other manner. The electrical contacts 160, 170 could be flat or substantially flat plates (e.g., rectangular, triangular, or other-shaped plates protruding from the housing 130). The electrical contacts 160, 170 could have a faceted geometry. For example, the electrical contacts 160, 170 could be triangular, rectangular, or other-shapes pyramids. The protruding aspects of the electrical contacts 160, 170 could have, for example, a characteristic size (e.g., diameter of cylinders, cones, or hemispheres, width of rectangular prisms or plates, or some other measure of size) between 1 and 5 millimeters. Further, the protruding aspects of the electrical contacts 160, 170 could have an inscribed, cast, and/or pressed texture or pattern. Additionally or alternatively, the exposed aspects of the electrical contacts 160, 170 could be roughened mechanically, chemically, or by some other method. Other geometries, sizes, surface treatments, and other aspects of the configuration of the electrical contacts 160, 170 are anticipated.

The housing 130 could be configured to be water-resistant. That is, the housing could be configured to include sealants, adhesives, gaskets, welds, press-fitted seams, and/or other joints such that the housing 130 was resistant to water entering an internal volume or volumes of the housing 130. Further, the interface between the housing 130 and the first and second electrical contacts 160, 170 protruding from the housing 130 could be configured such that the combination of the housing 130 and the electrical contacts 160, 170 is water-resistant.

The wearable device 100 includes electronics (not shown in FIG. 1) configured to measure the GSR of the skin at an external surface of the body proximate to the housing 130, using the first and second electrical contacts 160, 170 when the wearable device 100 is mounted to the external surface of the body. The electronics may include a GSR sensor configured to obtain a measurement relating to the GSR of the skin at the external surface of the body, via the first and second electrical contacts 160, 170, when a rectifier disposed in the wearable device 100 is reverse biased. The GSR sensor could include a reference voltage source electrically connected to the first electrical contact 160 through a resistor having a reference resistance. The GSR sensor may also include a voltage sensor electrically connected to the first electrical contact 160. The reference voltage source generates a reference voltage relative to the second electrical contact 170 and the voltage sensor measures a voltage between the first electrical contact 160 and the second electrical contact 170. A battery recharger could also be included in the electronics and electrically connected to the first electrical contact 160 through the rectifier.

A GSR of skin proximate to the electrical contacts 160, 170 could be determined based on a measurement relating to the GSR of the skin obtained using the GSR sensor when the wearable device 100 is mounted to the external surface of the body and when the rectifier is reverse biased. In some examples, the measurement relating to the GSR of the skin could include a measurement of the voltage between the first and second electrical contacts 160, 170, and the GSR of skin proximate to the electrical contacts 160, 170 could be determined based on the measured voltage, the value of a reference voltage produced by a reference voltage source, a resistance of a reference resistor, and/or other factors. For example, the GSR could be determined by calculating a multiple of the reference resistance corresponding to the measured voltage divided by a difference, where the difference is the measured voltage subtracted from the reference voltage. Other methods of determining a GSR could be used, for example a lookup table relating measured voltages to GSR values.

The electrical contacts 160, 170 protruding from the housing 130 could additionally be used for other purposes. For example, electronics disposed in the wearable device 100 could be used to sense an electrocardiogram (ECG) signal, a Galvanic skin potential (GSP), an electromyogram (EMG) signal, and/or some other physiological signal present at the electrical contacts 160, 170. Additionally or alternatively, the electrical contacts 160, 170 could be used to detect the presence of a charging device or some other electronic system electrically connected to the electrical contacts 160, 170.

In some examples, the housing 130 further includes at least one detector 150 for detecting at least one other physiological parameter, which could include any parameters that may relate to the health of the person wearing the wearable device. For example, the detector 150 could be configured to measure blood pressure, pulse rate, respiration rate, skin temperature, etc. At least one of the detectors 150 could be configured to non-invasively measure one or more targets in blood circulating in subsurface vasculature proximate to the wearable device. In a non-exhaustive list, detector 150 may include any one of an optical (e.g., CMOS, CCD, photodiode), acoustic (e.g., piezoelectric, piezoceramic), electrochemical (voltage, impedance), thermal, mechanical (e.g., pressure, strain), magnetic, or electromagnetic (e.g., RF, magnetic resonance) sensor.

The wearable device 100 may also include a user-interface 190 via which the wearer of the device may receive one or more recommendations or alerts generated from a remote server or other remote computing device, or from a processor within the device. The alerts could be any indication that can be noticed by the person wearing the wearable device. For example, the alert could include a visual component (e.g., textual or graphical information on a display), an auditory component (e.g., an alarm sound), and/or tactile component (e.g., a vibration). Further, the user-interface 190 may include a display 192 where a visual indication of the alert or recommendation may be displayed. The display 192 may further be configured to provide an indication the battery status of the device or an indication of any measured physiological parameters, for instance, the GSR being measured by the device.

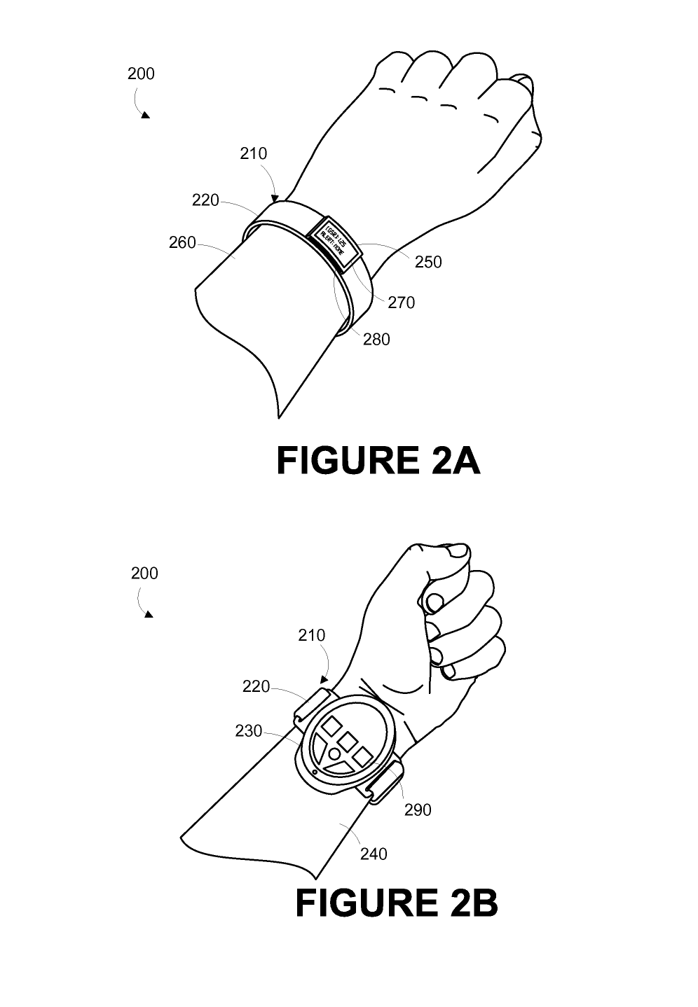

In some examples, the wearable device is provided as a wrist-mounted device, as shown in FIGS. 2A, 2B, 3A-3C, 4A, 4B, and 5A-5D. The wrist-mounted device may be mounted to the wrist of a living subject with a wristband or cuff, similar to a watch or bracelet. As shown in FIGS. 2A and 2B, the wrist mounted device 200 may include a mount 210 in the form of a wristband 220, a housing 230 positioned on the anterior side 240 of the wearer's wrist, and a user-interface 250 positioned on the posterior side 260 of the wearer's wrist. The wearer of the device may receive, via the user-interface 250, one or more recommendations or alerts generated either from a remote server or other remote computing device, or alerts generated by the operation of the wrist mounted device 200 (for example, alerts related to a GSR measured by the wrist mounted device 200). Such a configuration may be perceived as natural for the wearer of the device in that it is common for the posterior side 260 of the wrist to be observed, such as the act of checking a wrist-watch. Accordingly, the wearer may easily view a display 270 on the user-interface. Further, the housing 230 may be located on the anterior side 240 of the wearer's wrist. However, other configurations are contemplated.

The display 270 may be configured to display a visual indication of the alert or recommendation and/or an indication of the status of the wearable device or an indication of measured physiological parameters, for instance, the GSR of the skin being measured by the wrist mounted device 200. Further, the user-interface 250 may include one or more buttons 280 for accepting inputs from the wearer. For example, the buttons 280 may be configured to change the text or other information visible on the display 270. As shown in FIG. 2B, housing 230 may also include one or more buttons 290 for accepting inputs from the wearer. The buttons 290 may be configured to accept inputs for controlling aspects of the wrist mounted device 200, such as initiating a GSR measurement period, or inputs indicating the wearer's current health and/or affect state (i.e., normal, anxious, angry, calm, migraine, shortness of breath, heart attack, fever, “flu-like” symptoms, food poisoning, etc.).

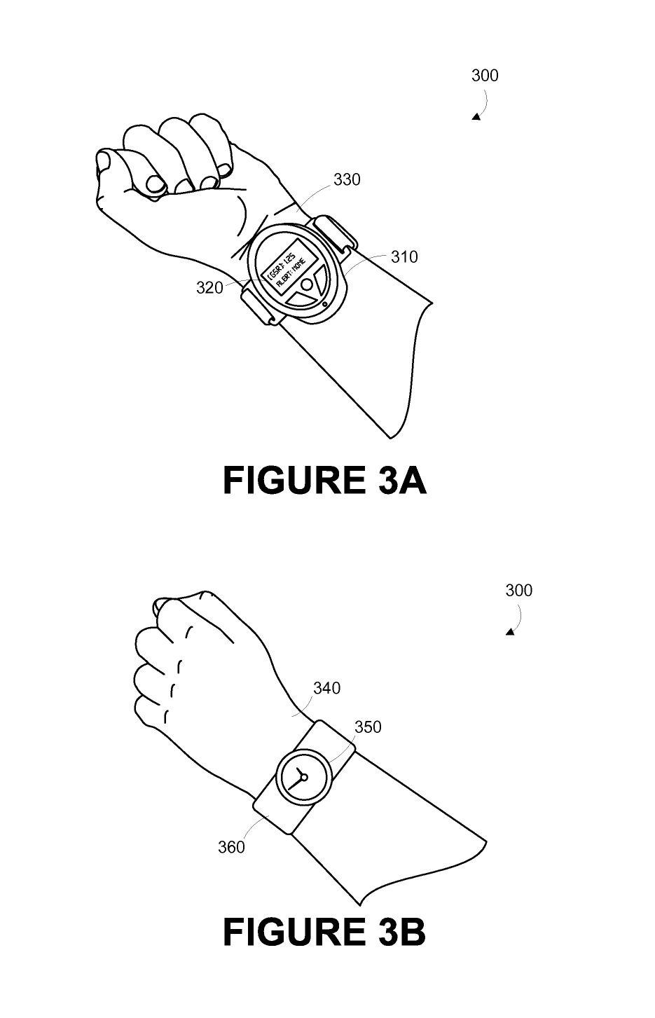

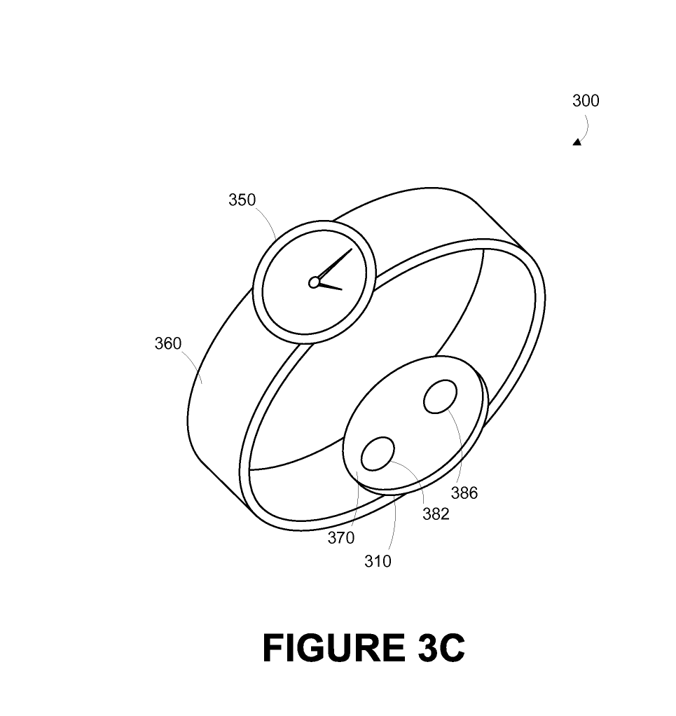

In another example wrist-mounted device 300, shown in FIGS. 3A-3C, the housing 310 and user-interface 320 are both provided on the same side of the wearer's wrist, in particular, the anterior side 330 of the wrist. On the posterior side 340, a watch face 350 may be disposed on the strap 360. While an analog watch is depicted in FIG. 3B, one of ordinary skill in the art will recognize that any type of clock may be provided, such as a digital clock.

As can be seen in FIG. 3C, the inner face 370 of the housing 310 is intended to be worn proximate to skin on an external surface of the wearer's body. A first electrical contact 382 and a second electrical contact 386 protrude from the inner face 370 of the housing 310 such that a measurement of the GSR of skin proximate to the inner face 370 could be measured using the electrical contacts 382, 386 when the wrist-mounted device 300 was mounted to a wrist of a wearer. The electrical contacts 382, 386 could also be used to charge a battery of the wrist-mounted device 300.

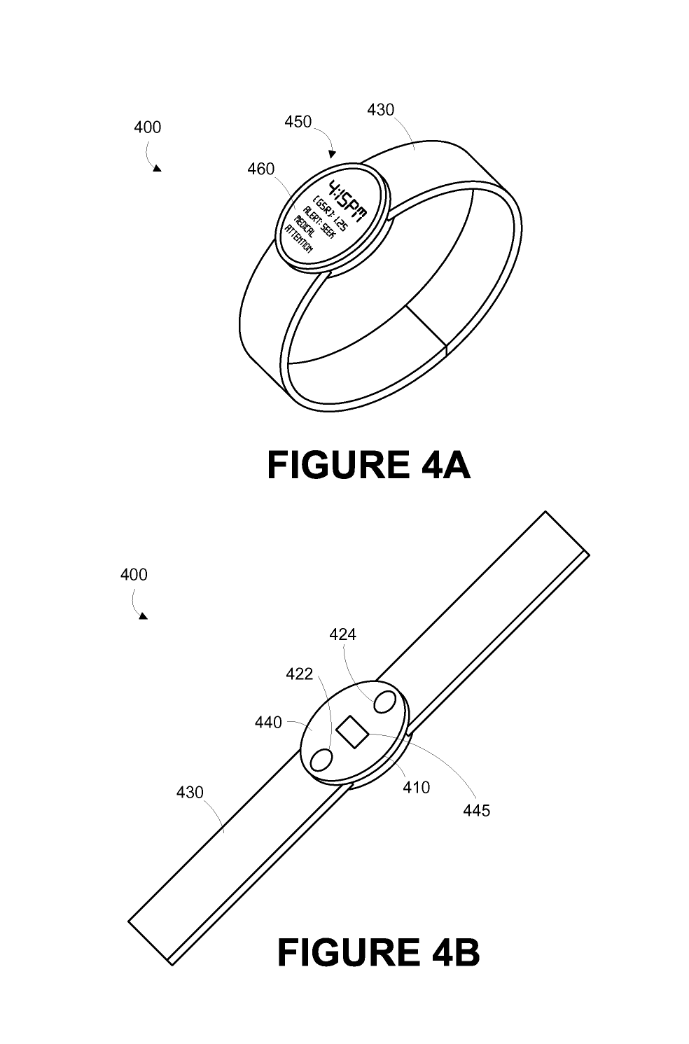

In a further example shown in FIGS. 4A and 4B, a wrist mounted device 400 includes a housing 410, disposed on a strap 430. Inner face 440 of housing 410 may be positioned proximate to a body surface so that a first electrical contact 422 and a second electrical contact 424 protruding from the housing 410 may be used to measure the GSR of skin of the body surface proximate to the housing 410. A detector 445 for detecting at least one other physiological parameter of the wearer could also be disposed on the inner face 440 of the housing 410. A user-interface 450 with a display 460 may be positioned facing outward from the housing 410. As described above in connection with other embodiments, user-interface 450 may be configured to display data about the wrist mounted device 400, including whether the wrist mounted device 400 is active, a GSR of skin proximate to the inner face 440 of the housing 410 measured using the first and second electrical contacts 422, 424, physiological data about the wearer obtained using the detector 445, and one or more alerts generated by a remote server or other remote computing device, or a processor located on the wrist mounted device 400. The user-interface 450 may also be configured to display the time of day, date, or other information that may be relevant to the wearer.

### III. EXAMPLE WEARABLE DEVICE CONFIGURATIONS

In examples, a wearable device such as any of the wearable devices described above may be designed such that the wrist band is easily detachable from the electronics module without requiring tools of any kind The wrist band can be replaced with a new band of different material or size to suit different functionalities.

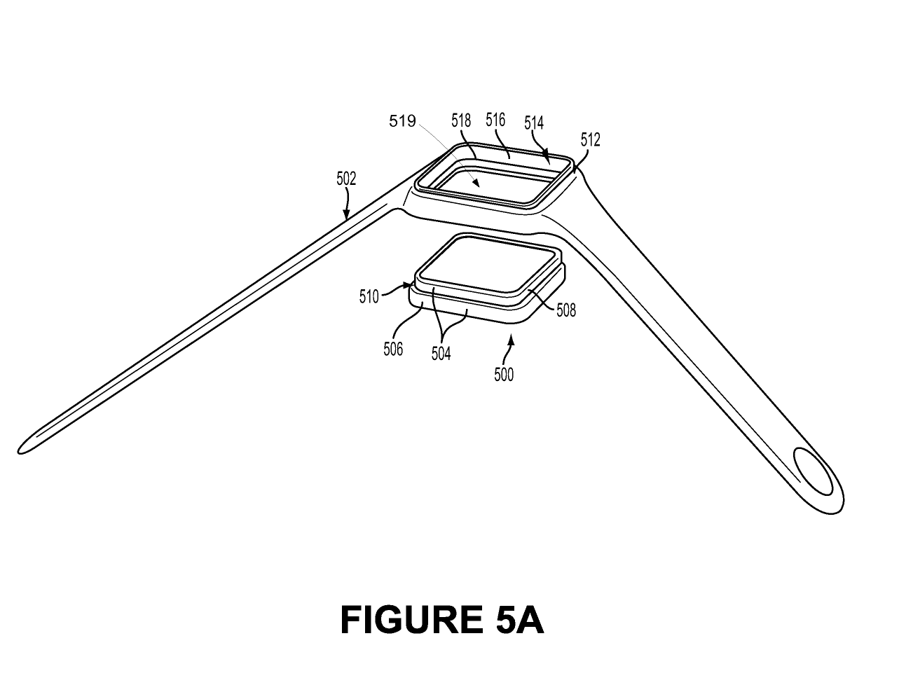

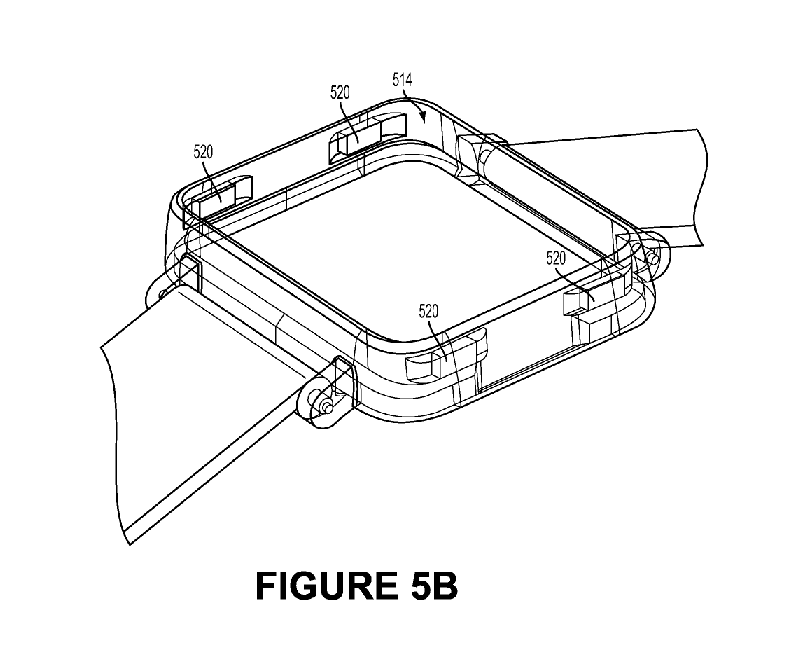

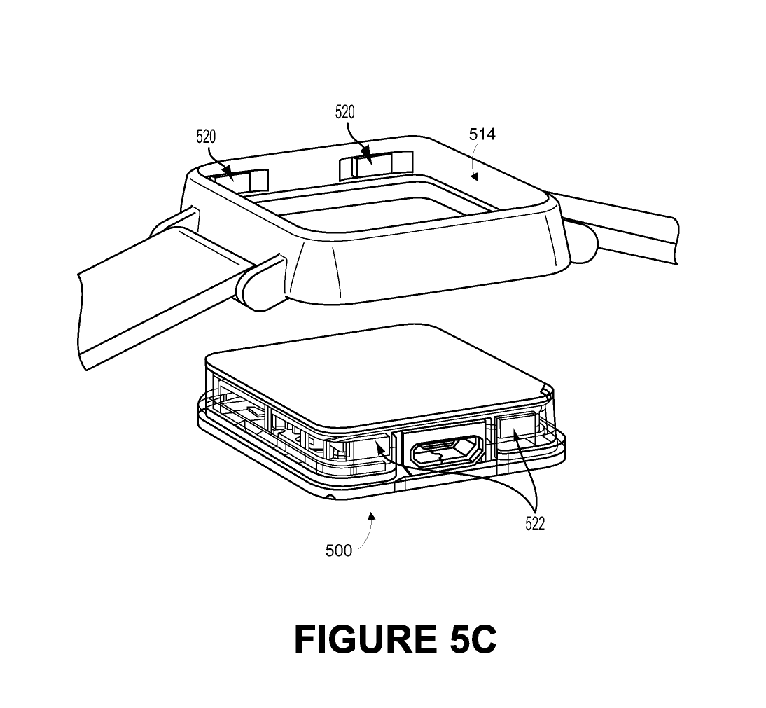

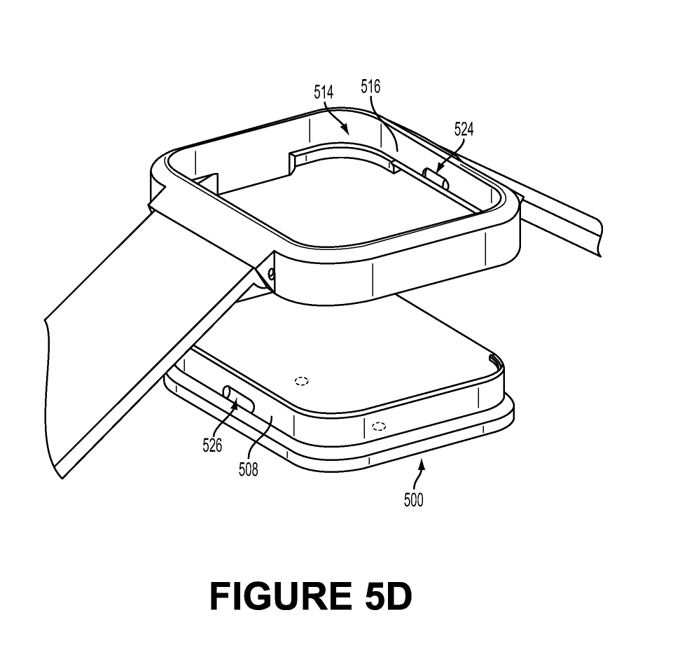

FIG. 5A illustrates a wearable device including an electronics module and a wrist band, in accordance with an example embodiment. FIG. 5A depicts an electronics module 500 and a wrist band or strap 502. The core electronics module 500 may include, for example, a first peripheral mating surface 504 extending around a periphery of the electronics module 500. The first peripheral mating surface 504 includes a first level portion 506 and a second level portion 508 that is substantially concentric with and extends from the first level portion 506. The word “substantially” is used herein to indicate that a center of the second level portion 508 is within a threshold value (e.g., threshold distance such as 0.2 mm or any other predefined) from a respective center of the first level portion 506.

As shown in FIG. 5A, the second level portion 508 is configured to meet the first level portion 506 at the periphery of the electronics module 500 to form a step 510. FIG. 5A depicts the step 510 as a sharp step; however, in some examples, the step 510 may include a sloped surface connecting the second level portion 508 with the first level portion 506. Also, FIG. 5A depicts the first level portion 506 and the second level portion 508 having rectangular or square shapes; however, the first level portion 506 and the second level portion 508 could have other shapes as well such as circular or oval shapes.

The strap 502 may include a holder 512. The holder 512 defines a frame 514. The frame 514 is configured to receive the electronics module 500. To receive the electronics module 500 within the frame 514, the frame 514 is configured to have a second peripheral mating surface 516 opposing the first peripheral mating surface 504 of the electronics module 500. The second peripheral mating surface 516 includes a respective step 518 configured to mate with the step 510 of the first peripheral mating surface 102 when the electronics module 500 is received within the frame 514.

The frame 514 also defines an opening 519. When the wearable device is worn about an external body location such as a wrist of a wearer, a biological sensor coupled to the electronics module 500 can be in contact with or proximate to skin of the wearer at a given wrist location through the opening 519. Thus, the sensor can measure a parameter via an external body surface proximate to the given wrist location.

FIG. 5B illustrates a plurality of magnets 520 positioned relative to the frame 514, in accordance with an example embodiment. In one example, to secure the electronics module 500 within the frame 514, the plurality of magnets 520 positioned relative to the frame 514 as shown in FIG. 5B may be used. For example, the magnets 520 may be configured to exert a magnetic force on the electronics module 500 that is sufficient to secure the electronics module 500 within the frame 514.

FIG. 5C illustrates the electronics module 500 having a respective plurality of magnets 522, in accordance with an example embodiment. As shown in FIG. 5C, the magnets 522 are disposed on the electronics module 500 at locations that correspond to the magnets 520 disposed on the frame 514. In this way, the interaction between the plurality of magnets 520 disposed on the frame 514 and the corresponding plurality of magnets 522 disposed on the electronics module 500 can provide a magnetic force that is sufficient to secure the electronics module 500 within the frame 514. In another example, instead of or in addition to the magnets 520 and 522, the frame 514 and the electronics module 500 may be made of or include magnetic materials. In this case, the magnetic force results from interaction between the magnetic material of the frame 514 and the respective magnetic material of the electronics module 500.

FIG. 5D illustrates a snap configuration for attaching the electronics module 500 to the wrist band or the strap 502, in accordance with an example embodiment. Alternative to or in addition to using magnets to secure the electronics module 500 within the frame 514, a snap configuration may be used. For instance, the frame 514 may be configured to have one or more protruding male portions, such as the protruding portion 524 in FIG. 5D, which protrude from the second peripheral mating surface 516. The electronics module 500 may be configured to have one or more recessed female portions such as the recessed female portion 526 in the first peripheral mating surface 504 (e.g., in the second level portion 508) corresponding to the one or more protruding male portions of the frame 514. In this case, as the electronics module 500 is received in the frame 514, the one or more protruding male portions and the recessed female portions engage in a snap configuration so as to secure the electronics module 500 within the frame 514.

Although FIG. 5D shows the frame 514 having the male protruding portions and the electronics module 500 having the recessed female portions, in other examples, the frame 514 may be configured to have the recessed female portions and the electronics module 500 may be configured to have the protruding male portions.

In the configurations shown in FIGS. 5A, 5B, 5C, and 5D, the electronics module 500 can be detached from the strap 502 without using tools. The strap 502 could be replaced with a new strap of different material or size to suit a user's taste or functionality. Also, these configurations allow for the electronics module 500 to be assembled to the strap 502 from behind or underneath, and thus capturing the electronics module 500 between the frame 514 and the external body surface (e.g., wrist location) when worn. Such configuration may prevent the electronics module 500 from becoming detached or lost when a user is performing strenuous activity, for example.

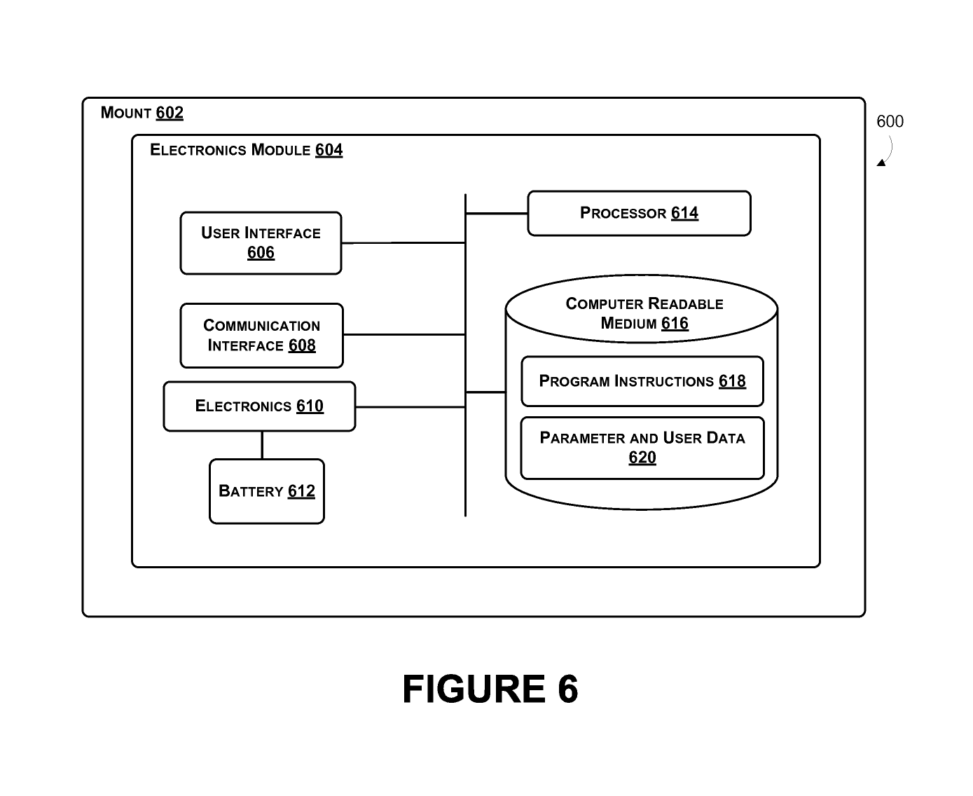

FIG. 6 is a functional block diagram of an example wearable device, in accordance with an example embodiment. The wearable device may take the form of or be similar to one of the wearable devices shown in FIGS. 1, 2A-B, 3A-3C, 4A-4C, and 5A-5D. However, the wearable device may also take other forms, for example, an ankle, waist, or chest-mounted device.

In particular, FIG. 6 shows an example of a wearable device 600 having a mount 602 and an electronics module 604. The mount 602 is configured for mounting the wearable device 600 to an external body surface. The electronics module 604 includes a user-interface 606, a communication interface 608, electronics 610, and battery 612 configured to power the electronics module 604. The electronics module 602 may also include a processor 614, a computer readable medium 616 having stored thereon program instructions 618 and parameter and user data 620.

The user-interface 606 may include a display, buttons, controls, or any other input/output means. The communication interface 608 may include, for example, an antenna configured to send and receive information to and from other devices or servers via a network connection. The communication interface 608 can optionally include one or more oscillators, mixers, frequency injectors, etc. to modulate and/or demodulate information on a carrier frequency to be transmitted and/or received by the antenna. In some examples, the communication interface 608 may be configured to indicate an output from the processor 614 by modulating an impedance of the antenna in a manner that is perceivable by a remote server or other remote computing device.

The electronics 610 could include sensors such as a GSR sensor or any other type of biological or physiological sensors. The GSR sensor could be configured to obtain a measurement relating to the GSR of the skin at the external body surface. The battery 612 may be a rechargeable battery configured to power the electronics module 604 and all components associated therewith.

The processor 614 may be a general-purpose processor or a special purpose processor (e.g., digital signal processors, application specific integrated circuits, etc.). The processor 614 can be configured to execute computer-readable program instructions 618 that are stored in a computer readable medium 616 and are executable to provide the functionality of the wearable device 600 described herein.

The computer readable medium 616 may include or take the form of one or more non-transitory, computer-readable storage media that can be read or accessed by the processor 614. The computer-readable storage media can include volatile and/or non-volatile storage components, such as optical, magnetic, organic or other memory or disc storage, which can be integrated in whole or in part with the processor 614. In some examples, the computer readable medium 616 can be implemented using a single physical device (e.g., one optical, magnetic, organic or other memory or disc storage unit), while in other examples the computer readable medium 616 can be implemented using two or more physical devices.

The program instructions 618 stored on the computer readable medium 616 may include instructions to perform or facilitate some or all of the device functionality described herein. For instance, program instructions 618 could include instructions to operate the electronics 610 and the sensors coupled thereto to make a GSR measurement (or any other type of measurement such as an optical measurement) via the sensors. The program instructions 618 could include instructions to operate based on the parameter and user data 620 stored in the computer readable medium 616 and/or modify the parameters and user data 620. For example, the parameters and user data 620 could include calibration data for the wearable device 600 and/or stored measurements made using the wearable device 600.

In an example, the program instructions 618 could further include instructions to determine the GSR based on calibration or other data stored in the parameters and user data 620. The instructions could include instructions to determine whether electronics module 604 is attached or coupled to the mount 602 and whether the wearable device 600 was mounted to skin on an external surface of a wearer based on the measurement relating to the GSR.

In another example, the program instructions 618 could include instructions to make a plurality of measurements and/or determinations of the GSR at a plurality of points in time using the electronics 610 and the sensors coupled thereto. The program instructions 618 could include instructions to store measurements of the GSR in the parameters and user data 620 and/or later or update calibration or other data in the parameters and user data 620 based on measurements of the GSR or other factors.

The program instructions 618 stored on the computer readable medium 616 could include instructions for powering the electronics module 604 using the battery 612.

In examples, the program instructions 618 can include instructions for operating the user-interface 606. For example, the program instructions 618 could include instructions for displaying a measured and/or determined GSR or other information generated by the electronics module 604, or for displaying one or more alerts generated by the electronics module 604 and/or received from an external system. Further, program instructions 618 may include instructions to execute certain functions based on inputs received via the user-interface 606, such as inputs received via one or more buttons disposed on or coupled to the user-interface 606.

In some examples, GSR or other measurements, wearer profiles, history of wearable device use, health state information input by device wearers and generated recommendations and clinical protocols may additionally be input to a cloud network and be made available for download by a wearer's physician or other authorized recipient. Trend and other analyses may also be performed on the collected data, such as physiological parameter data and health state information, in the cloud computing network and be made available for download by physicians or clinicians.

In an example, in response to a determination by instructions contained in the program instructions 618 that a medical condition is indicated, the electronics module 604 may generate an alert and communicate the alert to the user-interface 606. The alert may include a visual component, such as textual or graphical information displayed on a display, an auditory component (e.g., an alarm sound), and/or tactile component (e.g., a vibration). The textual information may include one or more recommendations, such as a recommendation that the wearer of the device contact a medical professional, seek immediate medical attention, or administer a medication.

Components of the wearable device 600 may be configured to work in an interconnected fashion with each other and/or with other components coupled to respective systems. One or more of the described functions or components of the wearable device 600 may be divided up into additional functional or physical components, or combined into fewer functional or physical components. In some further examples, additional functional and/or physical components may be added to the examples illustrated by FIG. 6.

### IV. EXAMPLE METHODS

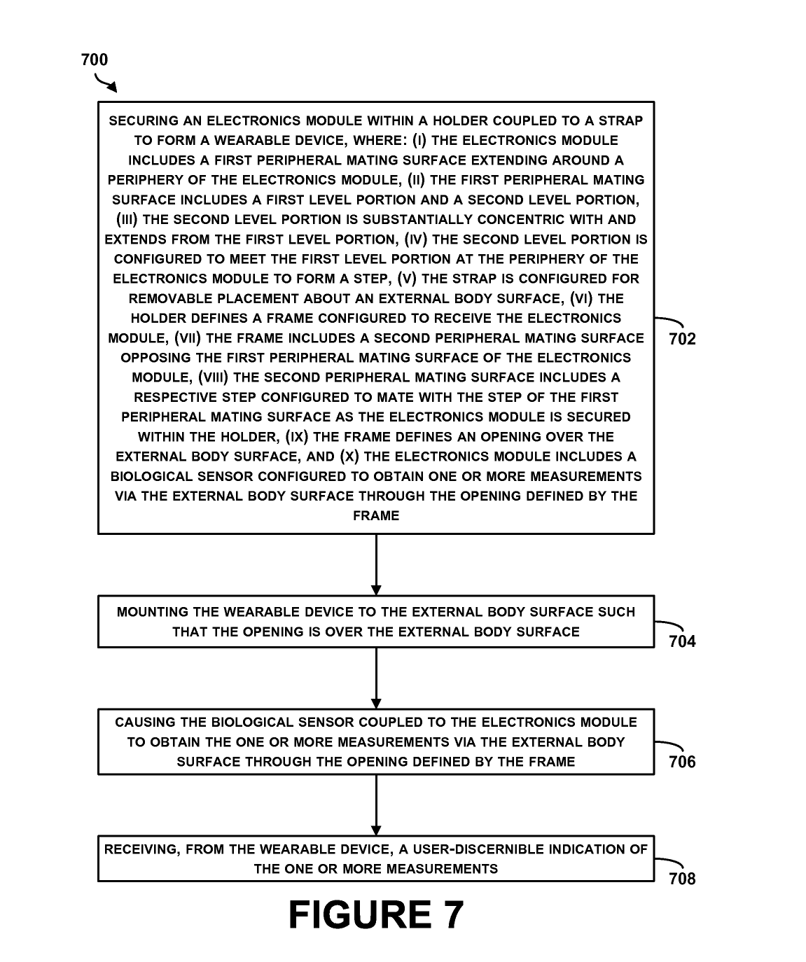

FIG. 7 is a flow chart of a method 700 of using a wearable device, in accordance with an example embodiment. The method 700 may include one or more operations, functions, or actions as illustrated by one or more of blocks 702-708. Although the blocks are illustrated in a sequential order, these blocks may in some instances be performed in parallel, and/or in a different order than those described herein. Also, the various blocks may be combined into fewer blocks, divided into additional blocks, and/or removed based upon the desired implementation.

At block 702, the method 700 includes securing an electronics module within a holder coupled to a strap to form a wearable device. As described in FIGS. 5A-5D, the electronics module may include a first peripheral mating surface extending around a periphery of the electronics module. The first peripheral mating surface includes a first level portion and a second level portion. The second level portion is substantially concentric with and extends from the first level portion. The second level portion is configured to meet the first level portion at the periphery of the electronics module to form a step. The strap is configured for removable placement about an external body surface. The holder defines a frame configured to receive the electronics module. The frame includes a second peripheral mating surface opposing the first peripheral mating surface of the electronics module. The second peripheral mating surface includes a respective step configured to mate with the step of the first peripheral mating surface as the electronics module is secured within the holder. The frame defines an opening over the external body surface. The electronics module includes a biological sensor configured to obtain one or more measurements via the external body surface through the opening defined by the frame.

In one example, to secure the electronics module within the frame defined by the holder, a plurality of magnets may be positioned relative to the frame as shown in FIG. 5B. The magnets are configured to exert a magnetic force on the electronics module to secure the electronics module within the frame. As shown in FIG. 5C, the electronics module may have a respective plurality of magnets that corresponds to the plurality of magnets positioned relative to the frame. In this case, the magnetic force results from interaction between the plurality of magnets positioned relative to the frame and the corresponding plurality of magnets in the electronics module.

In another example, a snap configuration may be used. For instance, the frame may be configured to have one or more protruding male portions that protrude from the second peripheral mating surface. The electronics module may be configured to have one or more recessed female portions such as the recessed female portion in the first peripheral mating surface (e.g., in the second level portion) corresponding to the one or more protruding male portions of the frame. In this case, as the electronics module is received in the frame, the one or more protruding male portions and the recessed female portions engage in a snap configuration so as to secure the electronics module within the frame. In other examples, the frame may be configured to have the recessed female portions and the electronics module may be configured to have the protruding male portions.

In examples, the electronics module may also include other components and sensors such as an accelerometer, a gyroscope, motion sensor, a location sensor, etc.

At block 704, the method 700 includes mounting the wearable device to the external body surface such that the opening is over the external body surface. The wearable device may be worn in a manner that positions the biological sensor proximate to a wrist location or any other body location in preparation for obtaining a measurement by the biological sensor. In some examples, the wearable device could be configured to be mounted to a wrist of a wearer where the strap is wrapped around the wrist (e.g., as shown in the embodiments illustrated in FIGS. 1, 2A-B, 3A-C, 4A-B, 5A-5D) such that the sensor contacts skin of the wrist of the wearer. In some examples, the mount includes an adhesive, and mounting the wearable device to an external body surface includes activating, applying, and/or exposing the adhesive and adhering the wearable device to the external body surface.

At block 706, the method 700 includes causing the biological sensor to obtain the one or more measurements via the external body surface. The biological sensor may be configured to obtain measurements when in contact with or proximate to the external body surface or skin about the wrist, for example. The measurement may be associated with a GSR or any other type of measurement such as an optical measurement.

At block 708, the method 700 includes receiving, from the wearable device, a user-discernible indication of the one or more measurements. In examples, the user-discernible indication may be provided by a display or any type of user-interface coupled to the electronics module. In another example, the user-discernible indication is provided by a user-interface coupled to the electronics module. In examples, the electronics module may further provide sensor information related to the measurements obtained by the biological sensor, e.g., via an antenna coupled to the electronics module, to other computing devices and/or servers.

Although the method 700 is described with respect to a strap or band mounted on a wrist, the method 700 is also applicable to other forms of wearable device such as an ankle, waist, or chest-mounted wearable device.

### V. CONCLUSION

It should be understood that arrangements described herein are for purposes of example only. As such, those skilled in the art will appreciate that other arrangements and other elements (e.g., machines, interfaces, functions, orders, and groupings of functions, etc.) can be used instead, and some elements may be omitted altogether according to the desired results. Further, many of the elements that are described are functional entities that may be implemented as discrete or distributed components or in conjunction with other components, in any suitable combination and location.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims, along with the full scope of equivalents to which such claims are entitled. It is also to be understood that the terminology used herein is for the purpose of describing particular embodiments only, and is not intended to be limiting.

Where example embodiments involve information related to a person or a device of a person, some examples may include privacy controls. Such privacy controls may include, at least, anonymization of device identifiers, transparency and user controls, including functionality that would enable users to modify or delete information relating to the user's use of a product.

Further, in situations in where embodiments discussed herein collect personal information about users, or may make use of personal information, the users may be provided with an opportunity to control whether programs or features collect user information (e.g., information about a user's medical history, social network, social actions or activities, profession, a user's preferences, or a user's current location), or to control whether and/or how such information is used. In addition, certain data may be treated in one or more ways before it is stored or used, so that personally identifiable information is removed. For example, a user's identity may be treated so that no personally identifiable information can be determined for the user, or a user's geographic location may be generalized where location information is obtained (such as to a city, ZIP code, or state level), so that a particular location of a user cannot be determined. Thus, the user may have control over how information is collected about the user and how the collected information is used.

What is claimed is:

1. A wearable device, comprising:
an electronics module having a first peripheral mating surface extending around a periphery of the electronics module, wherein the first peripheral mating surface includes a first level portion and a second level portion, wherein the second level portion is substantially concentric with and extends from the first level portion, and wherein the second level portion is configured to meet the first level portion at the periphery of the electronics module to form a step;
a strap configured for removable placement about an external body surface; and
a holder coupled to the strap, wherein the holder defines a frame configured to receive the electronics module, wherein the frame includes a second peripheral mating surface opposing the first peripheral mating surface of the electronics module, wherein the second peripheral mating surface includes a respective step configured to mate with the step of the first peripheral mating surface.

2. The wearable device of claim 1, further comprising:
a plurality of magnets positioned relative to the frame and configured to exert a magnetic force on the electronics module to secure the electronics module within the frame.

3. The wearable device of claim 2, wherein the electronics module includes a respective plurality of magnets corresponding to the plurality of magnets positioned relative to the frame, and wherein the magnetic force results from interaction between the plurality of magnets positioned relative to the frame and the corresponding plurality of magnets of the electronics module.

4. The wearable device of claim 2, wherein the electronics module includes a magnetic material such that the magnetic force results from interaction between the plurality of magnets positioned relative to the frame and the magnetic material of the electronics module.

5. The wearable device of claim 1, wherein the frame includes a magnetic material and the electronics module includes a respective magnetic material such that a magnetic force results from interaction between the magnetic material of the frame and the respective magnetic material of the electronics module, and wherein the magnetic force is sufficient to secure the electronics module within the frame.

6. The wearable device of claim 1, wherein the frame is configured to have one or more protruding male portions that protrude from the second peripheral mating surface, and wherein the electronics module is configured to have one or more recessed female portions in the first peripheral mating surface corresponding to the one or more protruding male portions of the frame such that, as the electronics module is received in the frame, the one or more protruding male portions and the female portions engage in a snap configuration to secure the electronics module within the frame.

7. The wearable device of claim 1, wherein the step formed as a result of the second level portion meeting the first level portion at the periphery of the electronics module comprises a sloped surface connecting the second level portion with the first level portion.

8. The wearable device of claim 1, wherein the external body surface is a wrist location.

9. The wearable device of claim 1, wherein the electronics module includes a biological sensor configured to obtain a measurement via the external body surface and a user-interface comprising at least a display, wherein the frame defines an opening through which the biological sensor can obtain the measurement via the external body surface, and wherein the display is configured to provide information associated with the measurement obtained by the biological sensor.

10. The wearable device of claim 1, wherein the electronics module further includes one or more of a motion sensor and a location sensor, data storage, and a touch sensor.

11. A method, comprising:
securing an electronics module within a holder coupled to a strap to form a wearable device, wherein: (i) the electronics module includes a first peripheral mating surface extending around a periphery of the electronics module, (ii) the first peripheral mating surface includes a first level portion and a second level portion, (iii) the second level portion is substantially concentric with and extends from the first level portion, (iv) the second level portion is configured to meet the first level portion at the periphery of the electronics module to form a step, (v) the strap is configured for removable placement about an external body surface, (vi) the holder defines a frame configured to receive the electronics module, (vii) the frame includes a second peripheral mating surface opposing the first peripheral mating surface of the electronics module, (viii) the second peripheral mating surface includes a respective step configured to mate with the step of the first peripheral mating surface as the electronics module is secured within the holder, (ix) the frame defines an opening over the external body surface, and (x) the electronics module includes a biological sensor configured to obtain one or more measurements via the external body surface through the opening defined by the frame;
mounting the wearable device to the external body surface such that the opening is over the external body surface;
causing the biological sensor coupled to the electronics module to obtain the one or more measurements via the external body surface through the opening defined by the frame; and
receiving, from the wearable device, a user-discernible indication of the one or more measurements.

12. The method of claim 11, wherein the frame includes a plurality of magnets configured to exert a magnetic force on the electronics module to secure the electronics module within the holder.

13. The method of claim 12, wherein the electronics module includes a respective plurality of magnets corresponding to the plurality of magnets of the frame, and wherein the magnetic force results from interaction between the plurality of magnets of the frame and the corresponding plurality of magnets of the electronics module.

14. The method of claim 12, wherein the electronics module includes a magnetic material such that the magnetic force results from interaction between the plurality of magnets positioned relative to the frame and the magnetic material of the electronics module.

15. The method of claim 11, wherein the frame includes a magnetic material and the electronics module includes a respective magnetic material such that a magnetic force results from interaction between the magnetic material of the frame and the respective magnetic material of the electronics module, and wherein the magnetic force is sufficient to secure the electronics module within the frame.

16. The method of claim 11, wherein the electronics module is configured to have one or more protruding male portions that protrude from the first peripheral mating surface, and wherein the frame is configured to have and one or more recessed female portions in the second peripheral mating surface corresponding to the one or more protruding male portions of the electronics module such that, as the electronics module is received in the frame, the one or more protruding male portions and the female portions engage in a snap configuration to secure the electronics module within the frame.

17. The method of claim 11, wherein the step formed as a result of the second level portion meeting the first level portion at the periphery of the electronics module comprises a sloped surface connecting the second level portion with the first level portion.

18. The method of claim 11, wherein the external body surface is a wrist location.

19. The method of claim 11, wherein the user-discernible indication is received at a display coupled to the electronics module.

20. The method of claim 11, wherein the electronics module further includes at least one of a motion sensor and a location sensor.
